(19) United States
(12) Patent Application Publication
(10) Pub. No.: US 2009/0117708 A1
(43) Pub. Date: May 7, 2009

(54) METHOD FOR MANUFACTURING SOI SUBSTRATE

(75) Inventors: Hideki Nishihata, Tokyo (JP); Nobuyuki Morimoto, Tokyo (JP); Akihiko Endo, Tokyo (JP)

Correspondence Address: DUANE MORRIS LLP - NY;PATENT DEPARTMENT, 1540 BROADWAY, NEW YORK, NY, 10036-4086, US

(73) Assignee: SUMCO CORPORATION

(21) Appl. No.: 11/933,882

(22) Filed: Nov. 1, 2007

(51) Int. Cl. H01L 21/30

(52) U.S. Cl. 438/459; 257/E21.211

(57) ABSTRACT

A method for manufacturing an SOI substrate includes steps of forming a first oxide film on a surface of a first silicon substrate; implanting hydrogen ions into the surface of the first silicon substrate on which the first oxide film is formed to form an ion implant region inside the first silicon substrate; removing the entire or the portion of first oxide film; forming a laminate by bonding the second silicon substrate to a hydrogen ion-implanted surface of the first silicon substrate with the first oxide film, or second oxide film formed on a surface of the second silicon substrate, or the first oxide film and second oxide film, interposed therebetween; and subjecting the laminate to a heat treatment at a predetermined temperature to separate the first silicon substrate along the ion implant region, thereby obtaining an SOI substrate including a thin SOI layer formed on the second silicon substrate with the oxide film interposed therebetween. The method can reduce a degree of contamination from heavy metals inside the SOI substrate.

### BACKGROUND OF THE INVENTION

1. Field of the Invention

The present invention relates to a method for manufacturing a Silicon-On-Insulator (SOI) substrate including an SOI layer formed on an oxide film by using a hydrogen-ion implantation technique.

2. Description of the Related Art

In the conventional art, a method for manufacturing an SOI substrate has been proposed which comprises forming an oxide film on a surface of a first silicon substrate; implanting the oxide film with hydrogen ions of high concentration to form an ion implant region at a predetermined depth from the surface of the silicon substrate; bonding a second silicon substrate to the first silicon substrate to form a laminate; heating the laminate to a temperature of 500° C. or higher to separate the first silicon substrate from the second silicon substrate along the hydrogen-ion implant region; and forming a semiconductor SOI layer on a surface of the second silicon substrate (for example, refer to Patent Document 1). With this method, an SOI substrate can be manufactured which comprises a second silicon substrate, an oxide film that is formed on the second silicon substrate and serves as an embedded oxide film, and a semiconductor SOI layer formed on the oxide film.

In this method for manufacturing an SOI substrate, if any foreign substances such as particles, organic matter, and the like are present on a bonded interface between the first silicon substrate and the second silicon substrate when they are bonded together, they may prevent the first silicon substrate and the second silicon substrate from being bonded, resulting in unbonded portions being formed on the bonded interface. The presence of unbonded portions on the bonded interface causes defects such as voids and blisters on the bonded interface of the resulting SOI substrate. In particular, if the adhesion of the bonded interface is weak, defects such as voids and blisters are likely to form even though a heat treatment for bonding is performed, and the sizes of such voids and blisters also tend to increase. In order to overcome this problem, a method is disclosed which comprises, prior to bonding a first silicon substrate and a second silicon substrate, cleaning and drying the first silicon substrate and the second silicon substrate, and then bonding these substrates (for example, refer to Patent Document 2). By thus cleaning and drying the first silicon substrate and the second silicon substrate prior to bonding them, it is possible to remove foreign substances such as particles, organic matter and the like present on the bonded interface between the first silicon substrate and the second silicon substrate, thereby preventing unbonded portions from being formed on the bonded interface of the resulting SOI substrate.

Patent Document 1

Japanese Unexamined Patent Application Publication No. 1993-211128(claims)

Patent Document 2

Japanese Unexamined Patent Application Publication No. 2003-309101(claims)

With these methods for manufacturing an SOI substrate which comprise implanting a first silicon substrate with hydrogen ions to form an ion implant region inside the first silicon substrate, bonding the first silicon substrate to a second silicon substrate, and separating the first silicon substrate along the ion implant region, even if foreign substances such as particles, organic matter, and the like present on the bonded interface between the first silicon substrate and the second silicon substrate can be removed by cleaning, there has been a problem that remains to be solved. That is, during the implantation of hydrogen ions, heavy metals such as Al and other SUS heavy metals (Fe, Cr, Ni and the like) used in the ion implanter and its parts are simultaneously implanted into the first silicon substrate to cause contamination from such heavy metals inside the first silicon substrate. Contamination from heavy metals produced inside the first silicon substrate during the implantation of hydrogen ions causes the yield to decrease in the subsequent processes of bonding and device manufacturing.

### SUMMARY OF THE INVENTION

Accordingly, the object of the present invention is to provide a method for manufacturing an SOI substrate whereby the degree of contamination from heavy metals inside the SOI substrate can be reduced.

As shown in FIG. 1, the invention according to claim 1 provides a method for manufacturing an SOI substrate, including steps of forming a first oxide film 21 on a surface of a first silicon substrate 14; implanting hydrogen ions into the surface of the first silicon substrate 14 on which the first oxide film 21 is formed to form an ion implant region 16 inside the first silicon substrate 14; removing the entire first oxide film 21; forming a second oxide film 22 on a surface of a second silicon substrate 12; forming a laminate 15 by bonding the second silicon substrate 12 to a hydrogen ion-implanted surface of the first silicon substrate 14 with the second oxide film 22 interposed therebetween; and subjecting the laminate 15 to a heat treatment at a predetermined temperature to separate the first silicon substrate 14 along the ion implant region 16, thereby obtaining an SOI substrate 11 including a thin SOI layer 13 formed on the second silicon substrate 12 with the second oxide film 22 interposed therebetween.

In the method for manufacturing SOI substrate according to claim 1, the first oxide film 21 formed on the surface of the first silicon substrate 14 is completely removed after implanting hydrogen ions into the first silicon substrate 14. This allows heavy metals implanted into the first silicon substrate 14 during the ion implantation step to be removed together with the first oxide film 21. Accordingly, the SOI substrate 11 thus obtained exhibits a reduced degree of internal contamination from heavy metals, compared with conventional SOI substrates from which the first oxide film 21 is not removed.

The invention according to claim 2 provides the method for manufacturing an SOI substrate according to claim 1, wherein the thickness of the first oxide film 21 formed on the surface of the first silicon substrate 14 may be from 30 to 500 nm.

In the method for manufacturing SOI substrate according to claim 2, heavy metals implanted into the first silicon substrate 14 during the ion implantation step can surely be removed from the first silicon substrate 14.

As shown in FIG. 2, the invention according to claim 3 provides a method for manufacturing an SOI substrate, including steps of forming a first oxide film 21 on a surface of a first silicon substrate 14; implanting hydrogen ions into the surface of the first silicon substrate 14 on which the first oxide film 21 is formed to form an ion implant region 16 inside the first silicon substrate 14; removing a portion of the first oxide film 21; forming a laminate 15 by bonding a second silicon substrate 12 to a hydrogen ion-implanted surface of the first silicon substrate 14 with the first oxide film 21 interposed therebetween; and subjecting the laminate 15 to a heat treatment at a predetermined temperature to separate the first silicon substrate 14 along the ion implant region 16, thereby obtaining an SOI substrate 11 including a thin SOI layer 13 formed on the second silicon substrate 12 with the first oxide film 21 interposed therebetween.

Also with the method for manufacturing SOI substrate according to claim 3, heavy metals implanted into the first silicon substrate 14 during the ion implantation step can be removed from the first oxide film 21, thereby reducing the degree of contamination from heavy metals inside the resulting SOI substrate 11. With this method, it is not necessary to form an oxide film on the second silicon substrate 12 separately, thereby making the process of manufacturing an SOI substrate simpler than that which includes forming an oxide film separately on the second silicon substrate 12.

The invention according to claim 4 provides the method for manufacturing an SOI substrate according to claim 3, wherein the thickness of a removed portion of the first oxide film 21 formed on the surface of the first silicon substrate 14 may be from 30 to 500 nm.

In the method for manufacturing SOI substrate according to claim 4, heavy metals implanted into the first silicon substrate 14 can surely be removed from the first silicon substrate 14.

As shown in FIG. 3, the invention according to claim 5 provides a method for manufacturing an SOI substrate, including steps of forming a first oxide film 21 on a surface of a first silicon substrate 14; implanting hydrogen ions into the surface of the first silicon substrate 14 on which the first oxide film 21 is formed to form an ion implant region 16 inside the first silicon substrate 14; removing a portion of the first oxide film 21; forming a second oxide film 22 on a surface of a second silicon substrate 12; forming a laminate 15 by bonding the second silicon substrate 12 to a hydrogen ion-implanted surface of the first silicon substrate 14 so that the second oxide film 22 is laminated to the first oxide film 21; and subjecting the laminate 15 to a heat treatment at a predetermined temperature to separate the first silicon substrate 14 along the ion implant region 16, thereby obtaining an SOI substrate 11 including a thin SOI layer 13 formed on the second silicon substrate 12 with the first oxide film 21 and the second oxide film 22 interposed therebetween.

Also with the method for manufacturing SOI substrate according to claim 5, heavy metals implanted into the first silicon substrate 14 during the ion implantation step can surely be removed from the first oxide film 21. This results in a reduced degree of contamination from heavy metals inside the resulting SOI substrate 11. Moreover, the SOI layer 13 is bonded to the second silicon substrate 12 with the first oxide film 21 and the second oxide film 22 interposed therebetween, which sufficiently ensures a thickness necessary for the oxide film even though the first oxide film 21 is partially removed.

The invention according to claim 6 provides the method for manufacturing SOI substrate according to claim 5, wherein the thickness of a removed portion of the first oxide film 21 formed on the surface of the first silicon substrate 14 may be from 30 to 500 nm.

In the method for manufacturing SOI substrate according to claim 5, heavy metals implanted into the first silicon substrate 14 can surely be removed from the first silicon substrate 14.

In the method for manufacturing an SOI substrate according to the invention, hydrogen ions are implanted into the surface of the first silicon substrate on which the first oxide film is formed to form an ion implant region inside the first silicon substrate, and then the entire or a portion of the first oxide film is removed. This allows heavy metals implanted into the first silicon substrate during the ion implantation step to be removed from the first silicon substrate together with the first oxide film. Accordingly, the SOI substrate 11 obtained as a final product exhibits a reduced degree of internal contamination from heavy metals, compared with conventional SOI substrates from which the first oxide film is not removed.

In the method, by removing a portion of the first oxide film, and bonding the first silicon substrate to the second silicon substrate with the first oxide film interposed therebetween, it is possible to obviate the need to form an oxide film separately on the second silicon substrate, thereby making the process of manufacturing an SOI substrate simpler than that which includes forming an oxide film separately on the second silicon substrate.

Moreover, by forming the second oxide film also on a surface of the second silicon substrate, the SOI layer of the resulting SOI substrate is bonded to the second silicon substrate, either with the second oxide film formed on the second silicon substrate interposed therebetween, or with the second oxide film and the first oxide film interposed therebetween. This sufficiently ensures a thickness necessary for the oxide film, even though a portion of or the entire first oxide film is removed.

### BRIEF DESCRIPTION OF THE DRAWINGS

FIG. 1 is a flowchart showing a method for manufacturing an SOI substrate according to a first embodiment of the invention;

FIG. 2 is a flowchart showing a method for manufacturing an SOI substrate according to a second embodiment of the invention;

FIG. 3 is a flowchart showing a method for manufacturing an SOI substrate according to a third embodiment of the invention;

FIG. 4 is a diagram showing the results of first comparison test for examples according to the invention;

FIG. 5 is a diagram showing the results of second comparison test for examples according to the invention; and

FIG. 6 is a diagram showing the results of third comparison test for examples according to the invention.

### DETAILED DESCRIPTION OF THE PREFERRED EMBODIMENTS

A first embodiment for carrying out the invention is described with reference to the attached drawings hereinafter.

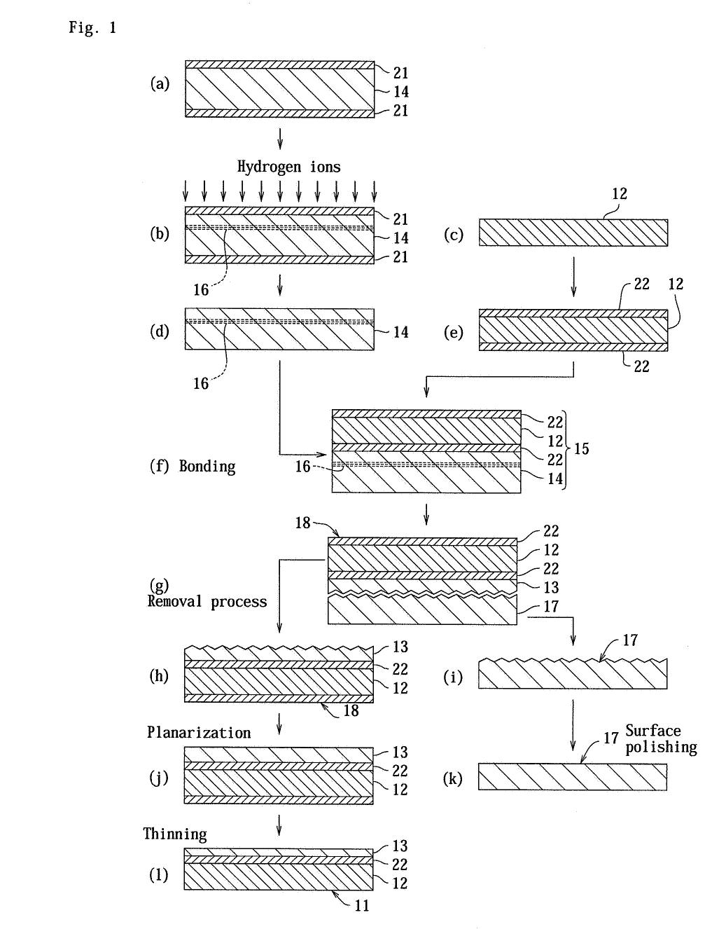

As shown in FIG. 1(l), an SOI substrate 11 comprises a second silicon substrate 12 composed of silicon single crystal, and an SOI layer 13 composed of silicon single crystal which is bonded to the second silicon substrate 12 with a second oxide film 22 interposed therebetween. The second silicon film 22 is a silicon oxide film (SiO₂ film) with insulating properties, and is initially formed on the second silicon substrate 12. While the thickness of the SOI layer 13 is preferably from 10 to 200 nm, and more preferably 10 to 70 nm, the actual thickness of the SOI layer 13 depends on the need of device manufacturers and is not limited.

The method for manufacturing such an SOI substrate 11 according to the first embodiment of the invention is explained.

A first silicon substrate 14 composed of silicon single crystal is prepared first. A first oxide film 21 composed of a silicon oxide film (SiO₂ film) with insulating properties is then formed not only on a top surface of the first silicon substrate 14 but on the entire surfaces thereof, including rear and side surfaces (not illustrated), by thermal oxidation (FIG. 1(a)). The first oxide film 21 has a thickness of 30 to 500 nm, and preferably 50 to 350 nm. The first oxide film 21 may also be formed on the surfaces of the first silicon substrate 14 using the chemical vapor deposition (CVD) technique instead of thermal oxidation.

Hydrogen ions are next implanted into the top surface of the first silicon substrate 14 at a dose of 4×10¹⁶ to 10×10¹⁶ atoms/cm² and at an energy level of 20 to 200 keV. This results in the formation of an ion implant region 16 inside the first silicon substrate 14 (FIG. 1(b)). The dose of hydrogen ions is herein limited to the range of 4×10¹⁶ to 10×10¹⁶ atoms/cm² because if the dose is less than 4×10¹⁶/cm², cleavage cannot be achieved in a first heat treatment, whereas if it exceeds 10×10¹⁶/cm², the top surface of the first silicon substrate 14 will flake off during the implantation of hydrogen ions, thus easily causing particles to be generated. The energy level is limited to the range of 20 to 200 keV because if it is less than 20 keV, the SOI layer 13 becomes too thin, whereas if it exceeds 200 keV, a special ion implanter will be necessary.

The entire first oxide film 21 is then removed (FIG. 1(d)). The removal of the first oxide film 21 is performed by HF cleaning to remove the entire first oxide film 21, together with heavy metals implanted thereinto during the ion implantation step. Therefore, the thickness of the first oxide film 21 is preferably from 30 to 500 nm, and more preferably from 50 to 350 nm. If the thickness of the first oxide film 21 is less than 30 nm, it will be difficult to sufficiently eliminate contamination from implanted heavy metals, and moreover, heavy metals are not implanted into regions deeper than 500 nm by ion implantation at an energy level of 200 keV or less. Note that the first oxide film 21 may also be removed using reactive ion etching or ECR plasma etching instead of HF cleaning.

A second silicon substrate 12 composed of silicon single crystal with the same surface area as that of the first silicon substrate 14 is prepared separately (FIG. 1(c)). A second oxide film 22 composed of a silicon oxide film (SiO₂ film) with insulating properties is then formed not only on a top surface of the second silicon substrate 12 but on the entire surfaces thereof, including rear and side surfaces (not illustrated), by thermal oxidation (FIG. 1(e)). The second oxide film 22 has a thickness of 10 to 300 nm, and preferably 50 to 200 nm. The thickness of the second oxide film 22 is limited to the range of 10 to 300 nm because if it is less than 10 nm, a blister eliminating effect obtained by utilizing the fluidity of an oxide film at high temperatures when the second oxide film 22 is bonded to the first silicon substrate 14 as described below decreases, thus easily resulting in the formation of blisters; whereas if it exceeds 300 nm, the uniformity of the embedded oxide film decreases below the device requirements. Note that the second oxide film (SiO₂ film) may also be formed only on the top surface of the second silicon substrate 12 by the CVD technique instead of thermal oxidation.

The second silicon substrate 12 is then laminated to the hydrogen ion-implanted surface of the first silicon substrate 14 with the second oxide film 22 interposed therebetween, thereby forming a laminate 15 (FIG. 1(f)). The formation of the laminate 15 comprises laminating the second silicon substrate 12 to the first silicon substrate 14 and aligning them; and applying a load onto the center of the second silicon substrate 12 formed on the first silicon substrate 14 in the direction of the first silicon substrate 14. Applying a load to the laminate of the second silicon substrate 12 and the first silicon substrate 14 causes gases present between them to be gradually discharged from the periphery of these substrates. Therefore, the area of the bonded interface between the first silicon substrate 14 and the second silicon substrate 12 is enlarged to the total area of the bonded main surface of the first silicon substrate 14 or second silicon substrate 12 when these substrates have been bonded. Upon bonding of these substrates, a laminate 15 of the first silicon substrate 14 and the second silicon substrate 12 can be obtained.

The laminate 15 is subsequently subjected to a first heat treatment by being maintained in a nitrogen atmosphere at 400 to 800° C., and preferably 450 to 600° C., for 1 to 30 minutes, and preferably 10 to 30 minutes. The first silicon substrate 14 is thus split along the ion implant region 16 that corresponds to a region near the peak position of hydrogen ion implantation, thereby being separated into a thick lower portion 17 and a thin upper portion 13 (FIG. 1(g)). The upper SOI layer 13 is tightly attached to the second silicon substrate 12 with the second oxide film 22 interposed therebetween to form a laminated substrate 18 (FIG. 1(h)). The thick lower portion 17 is recycled by polishing the separated surface thereof later (FIGS. 1(i) and (k)).

The laminated substrate 18 is then planarized and thinned to a final thickness using a general technique. For example, any region that has been damaged during separation is removed by chemical mechanical polishing (CMP), oxidation, or the like, and then the laminated substrate 18 is subjected to a heat treatment to enhance the lamination strength. The laminated substrate 18 is further subjected to, for example, CMP and a high-temperature heat treatment in an atmosphere such as hydrogen, argon or the like so as to be planarized (FIG. 1(j)). The laminated substrate 18 is then thinned by, for example, CMP and oxidation until a predetermined thickness is achieved for the SOI layer 13, thereby obtaining the SOI substrate 11 (FIG. 1(l)).

In this method for manufacturing the SOI substrate 11, the first oxide film 21 formed on the surfaces of the first silicon substrate 14 is completely removed after implanting the first silicon substrate 14 with hydrogen ions. This allows heavy metals implanted into the first silicon substrate 14 during the ion implantation step to be removed together with the first oxide film 21. Therefore, in the SOI substrate 11 consequently obtained by forming the laminate 15 by bonding the second silicon substrate 12 to the hydrogen ion-implanted surface of the first silicon substrate 14, and then separating the laminate 15 along the hydrogen-ion implant region 16, the degree of internal contamination from heavy metals can be reduced, compared with conventional SOI substrates from which the first oxide film 21 is not removed.

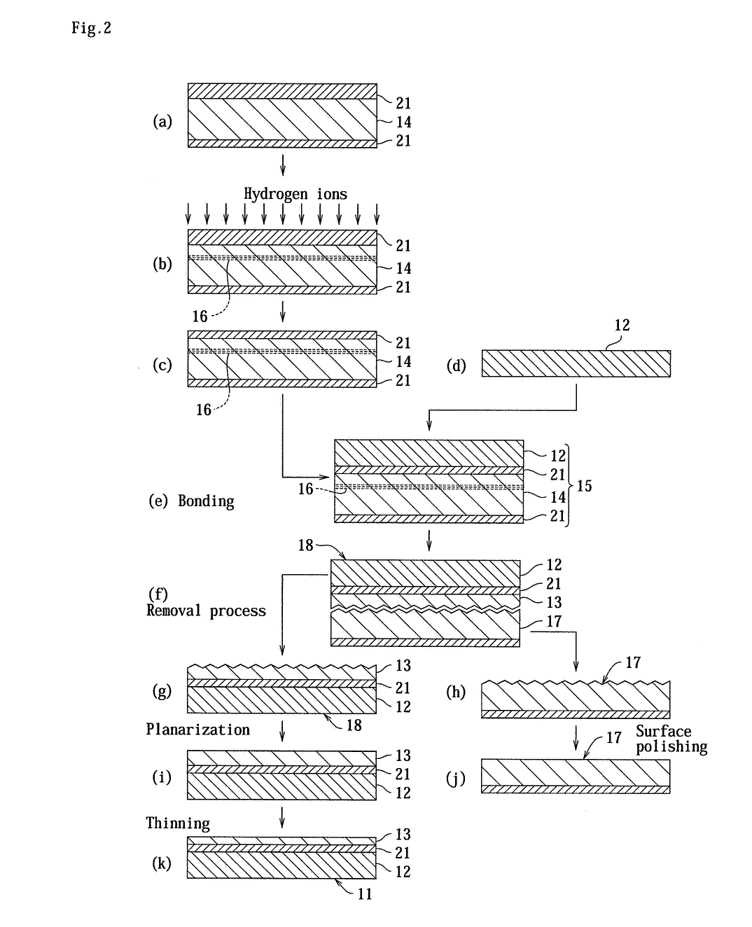

A second embodiment of the invention is described with reference to FIG. 2. In FIG. 2, the same reference numerals as used in the first embodiment denote the same parts, and the explanation thereof is not repeated.

As shown in FIG. 2(k), an SOI substrate 11 comprises a second silicon substrate 12 composed of silicon single crystal, and an SOI layer 13 composed of silicon single crystal which is bonded to the second silicon substrate 12 with a first oxide film 21 interposed therebetween. The first oxide film 21 is a silicon oxide film (SiO₂ film) with insulating properties, and is initially formed on the first silicon substrate 14.

The method for manufacturing such an SOI substrate 11 according to the second embodiment of the invention is explained.

A first silicon substrate 14 composed of silicon single crystal is prepared first. A first oxide film 21 composed of a silicon oxide film (SiO₂ film) with insulating properties is then formed not only on a top surface of the first silicon substrate 14 but on the entire surfaces thereof, including rear and side surfaces (not illustrated), by thermal oxidation (FIG. 2(a)). The first oxide film 21 may also be formed only on the top surface of the first silicon substrate 14 using the CVD technique instead of thermal oxidation. Hydrogen ions are then implanted into the top surface of the first silicon substrate 14 (FIG. 2(b)). Since the conditions and procedure of the implantation are the same as described above, the explanation is not repeated.

A portion of the first oxide film 21 is then removed (FIG. 2(c)). The removal of the first oxide film 21 is performed by, for example, HF cleaning, to remove heavy metals implanted into the first oxide film 21 during the ion implantation step. The thickness of the first oxide film 21 that is removed is preferably from 30 to 500 nm, and more preferably from 50 to 350 nm. A portion of the original first oxide film 21 is thus removed partially so that the thickness of the first oxide film 21 remaining on the first silicon substrate 14 is from 10 to 300 nm, and preferably from 50 to 200 nm. The thickness of the first oxide film 21 remaining on the first silicon substrate 14 is limited to the range of 10 to 300 nm because if it is less than 10 nm, a blister eliminating effect obtained by utilizing the fluidity of an oxide film at high temperatures when the first silicon substrate 14 is bonded to the second oxide film 22 as described below decreases, thus easily resulting in the formation of blisters; whereas if it exceeds 300 nm, the uniformity of the embedded oxide film decreases below the device requirements. If the thickness of the first oxide film 21 removed is less than 30 nm, it will be difficult to sufficiently eliminate contamination from implanted heavy metals, and moreover, heavy metals are not implanted into regions deeper than 500 nm by ion implantation at an energy level of 200 keV or less.

A second silicon substrate 12 composed of silicon single crystal with the same surface area as that of the first silicon substrate 14 is prepared separately (FIG. 2(d)). Then, without forming an oxide film on any surface of the second silicon substrate 12, the second silicon substrate 12 is bonded to the hydrogen ion-implanted surface of the first silicon substrate 14 with the first oxide film 21 interposed therebetween to form a laminate 15 (FIG. 2(e)). The laminate 15 is then subjected to a first heat treatment in the same manner as described in the first embodiment and is thereby split along an ion implant region 16. The first silicon substrate 14 is thus separated into a thick lower portion 17 and a thin upper SOI layer 13 (FIG. 2(f)). The resulting laminated substrate 18 is then planarized and thinned to a final thickness using a general technique, as described in the first embodiment (FIGS. 2(g) and (i)), thus giving an SOI substrate 11 (FIG. 2(k)).

In this method for manufacturing the SOI substrate 11, the first oxide film 21 formed on the surfaces of the first silicon substrate 14 is partially removed after implanting the first silicon substrate 14 with hydrogen ions. This allows heavy metals implanted into the first silicon substrate 14 during the ion implantation step to be removed from the first oxide film 21. Therefore, in the SOI substrate 11 consequently obtained by forming the laminate 15 by bonding the second silicon substrate 12 to the first silicon substrate 14, and then separating the laminate 15 along the hydrogen-ion implant region 16, the degree of internal contamination from heavy metals can be reduced, compared with conventional SOI substrates from which the first oxide film 21 is not partially removed.

Moreover, the SOI layer 13 is bonded to the second silicon substrate 12 with the first oxide film 21 remaining on the first silicon substrate 14 interposed therebetween. This obviates the need to form an oxide film on the second silicon substrate 12 separately, thereby making the process of manufacturing an SOI substrate simpler than that which comprises forming an oxide film separately on the second silicon substrate 2.

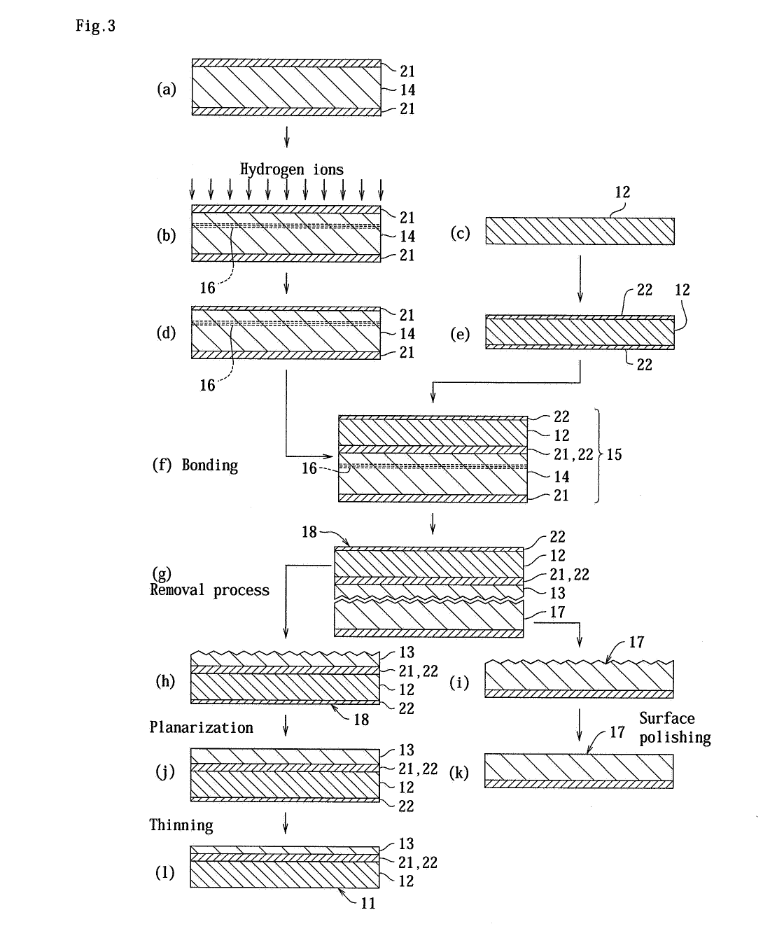

A third embodiment of the invention is described with reference to FIG. 3. In FIG. 3, the same reference numerals as used in the first embodiment denote the same parts, and the explanation thereof is not repeated.

As shown in FIG. 3(l), an SOI substrate 11 comprises a second silicon substrate 12 composed of silicon single crystal, and an SOI layer 13 composed of silicon single crystal which is bonded to the second silicon substrate 12 with a first oxide film 21 and a second oxide film 22 interposed therebetween. The first oxide film 21 and the second oxide film 22 are silicon oxide films (SiO₂ films) with insulating properties. The first oxide film 21 is initially formed on a first silicon substrate 14, and the second oxide film 22 is initially formed on the second silicon substrate 12.

The method for manufacturing such an SOI substrate 11 according to the third embodiment of the invention is explained.

A first silicon substrate 14 composed of silicon single crystal is prepared first. A first oxide film 21 composed of a silicon oxide film (SiO₂ film) with insulating properties is then formed not only on a top surface of the first silicon substrate 14 but on the entire surfaces thereof, including rear and side surfaces (not illustrated), by thermal oxidation (FIG. 3(a)). The first oxide film 21 may also be formed on the surfaces of the first silicon substrate 14 using the CVD technique instead of thermal oxidation. Hydrogen ions are then implanted into the top surface of the first silicon substrate 14 (FIG. 3(b)). Since the conditions and procedure of the implantation are the same as described above, the explanation is not repeated.

A portion of the first oxide film 21 is then removed (FIG. 3(d)). The removal of the first oxide film 21 is performed by, for example, HF cleaning, to remove heavy metals implanted into the first oxide film 21 during the ion implantation step. The thickness of the first oxide film 21 that is removed is preferably from 30 to 500 nm, and more preferably from 50 to 350 nm. A portion of the original first oxide film 21 is thus removed partially so that the thickness of the first oxide film 21 remaining on the first silicon substrate 14 is from 10 to 300 nm, and preferably from 50 to 200 nm. If the thickness of the first oxide film 21 removed is less than 30 nm, it will be difficult to sufficiently eliminate contamination from implanted heavy metals, and moreover, heavy metals are not implanted into regions deeper than 500 nm by ion implantation at an energy level of 200 keV or less. The thickness of the first oxide film 21 remaining on the surfaces of the first silicon substrate 14 is limited to the range of 10 to 300 nm because if it is less than 10 nm, a blister eliminating effect obtained by utilizing the fluidity of an oxide film at high temperatures when the first silicon substrate 14 is bonded to the second silicon substrate 12 as described below decreases, thus easily resulting in the formation of blisters; whereas if it exceeds 300 nm, the uniformity of the embedded oxide film decreases below the device requirements.

A second silicon substrate 12 composed of silicon single crystal with the same surface area as that of the first silicon substrate 14 is prepared separately (FIG. 3(c)). A second oxide film 22 composed of a silicon oxide film (SiO₂ film) with insulating properties is then formed not only on a top surface of the second silicon substrate 12 but on the entire surfaces thereof, including rear and side surfaces (not illustrated), by thermal oxidation (FIG. 3(e)). A portion of the second oxide film 22 is removed partially so that the sum of the thicknesses of the second oxide film 22 and the first oxide film 21 remaining on the top surface of the first silicon substrate 14 becomes 10 to 300 nm, and preferably 50 to 200 nm. Note that the second oxide film (SiO₂ film) may also be formed only on the top surface of the second silicon substrate 12 by the CVD technique instead of thermal oxidation.

The second silicon substrate 12 is then bonded to the hydrogen ion-implanted surface of the first silicon substrate 14 with the first oxide film 21 and the second oxide film 22 interposed therebetween, thereby forming a laminate 15 (FIG. 3(f)). The laminate 15 is then subjected to a first heat treatment as described in the first embodiment and is thereby split along an ion implant region 16. The first silicon substrate 14 is thus separated into a thick lower portion 17 and a thin upper SOI layer 13 (FIG. 3(g)). The resulting laminated substrate 18 is then planarized and thinned to a final thickness using a general technique, as described in the first embodiment (FIGS. 3(h) and (j)), thus giving an SOI substrate 11 (FIG. 3(l)).

In this method for manufacturing the SOI substrate 11, the first oxide film 21 formed on the surfaces of the first silicon substrate 14 is partially removed after implanting the first silicon substrate 14 with hydrogen ions. This allows heavy metals implanted into the first silicon substrate 14 during the ion implantation step to be removed from the first oxide film 21. Therefore, in the SOI substrate 11 consequently obtained by forming the laminate 15 by bonding the second silicon substrate 12 to the hydrogen ion-implanted surface of the first silicon substrate 14, and then separating the laminate 15 along the hydrogen-ion implant region 16, the degree of internal contamination from heavy metals can be reduced, compared with conventional SOI substrates from which the first oxide film 21 is not partially removed.

Moreover, the SOI layer 13 is bonded to the second silicon substrate 12 with the first oxide film 21 and the second oxide film 22 interposed therebetween. This sufficiently ensures a thickness necessary for the oxide film, even though the first oxide film 21 is partially removed.

### EXAMPLE

Next, examples according to the present invention are explained together with a comparative example.

### First Example

As shown in FIG. 1, a first silicon substrate 14 that is composed of silicon single crystal and has an outer diameter of 300 mm and a thickness of 0.78 mm was first subjected to a heat treatment by being maintained in a wet oxygen atmosphere at 1000° C. for 15 minutes, so as to form a first oxide film 21 with a thickness of 100 nm on the surfaces of the first silicon substrate 14. Then, hydrogen ions were implanted into the top surface of the first silicon substrate 14 at a dose of 6×10¹⁶/cm² and at an energy level of 50 keV to form an ion implant region 16 inside the first silicon substrate 14 (FIG. 1(b)). The entire first oxide film 21 was subsequently removed by HF etching (FIG. 1(d)).

A second silicon substrate 12 with the same shape and size as those of the first silicon substrate 14 was prepared separately (FIG. 1(c)). The second silicon substrate 12 was then subjected to a heat treatment by being maintained in a wet oxygen atmosphere at 1000° C. for 20 minutes, so as to form a second oxide film 22 with a thickness of 150 nm on the surfaces of the second silicon substrate 12 (FIG. 1(e)). The second silicon substrate 12 was tightly attached to the hydrogen ion-implanted surface of the first silicon substrate 14, with the second oxide film 22 interposed therebetween, thereby forming a laminate 15 (FIG. 1(f)).

The laminate 15 was then subjected to a heat treatment in a nitrogen atmosphere at 500° C. for 30 minutes to be split along the ion implant region 16, thus resulting in a laminated substrate 18 in which an upper SOI layer 13 was tightly attached to the second silicon substrate 12 with the second oxide film 22 therebetween (FIG. 1(h)). Any layer that has been damaged during removal was removed from the laminated substrate 18 through oxidation, and then the laminated substrate 18 was subjected to a high-temperature heat treatment in an argon atmosphere to completely strengthen the adhesion of the laminated interface. The top surface of the laminated structure 18 was then planarized (FIGS. 1(h) and (j)). The laminated structure 18 was subsequently thinned until a predetermined thickness was achieved for the SOI layer through a heat treatment in an oxidizing atmosphere. The SOI substrate 11 according to first example was thus obtained (FIG. 1(l)).

### Second Example

As shown in FIG. 2, a first silicon substrate 14 that is composed of silicon single crystal and has an outer diameter of 300 mm and a thickness of 0.78 mm was first subjected to a heat treatment by being maintained in a wet oxygen atmosphere at 1000° C. for 40 minutes, so as to form a first oxide film 21 with a thickness of 250 nm on the surfaces of the first silicon substrate 14. Then, hydrogen ions were implanted into the top surface of the first silicon substrate 14 at a dose of 6×10¹⁶/cm² and at an energy level of 50 keV to form an ion implant region 16 inside the first silicon substrate 14 (FIG. 2(b)). A 100 nm portion of the first oxide film 21 was subsequently removed by HF etching, so that the first oxide film 21 with a thickness of 150 nm remained on the first silicon substrate 14 (FIG. 2(c)).

A second silicon substrate 12 with the same shape and size as those of the first silicon substrate 14 was prepared separately (FIG. 2(d)). Without forming an oxide film on the second silicon substrate 12, the second silicon substrate 12 was tightly attached to the hydrogen ion-implanted surface of the first silicon substrate 14 with the first oxide film 21 interposed therebetween, thereby forming a laminate 15 (FIG. 2(e)). The laminate 15 was then subjected to a heat treatment in a nitrogen atmosphere at 500° C. for 30 minutes to be split along the ion implant region 16 (FIG. 2(f)), thus resulting in a laminated substrate 18 in which an upper SOI layer 13 was tightly attached to the second silicon substrate 12 with the first oxide film 21 therebetween (FIG. 2(g)). Any layer that has been damaged during removal was removed from the laminated substrate 18 through oxidation, and then the laminated substrate 18 was subjected to a high-temperature heat treatment in an argon atmosphere to completely strengthen the adhesion of the laminated interface. The top surface of the laminated structure 18 was then planarized (FIGS. 2(g) and (i)). The laminated structure 18 was subsequently thinned until a predetermined thickness was achieved for the SOI layer through a heat treatment in an oxidizing atmosphere. The SOI substrate 11 according to second example was thus obtained (FIG. 2(k)).

### Third Example

As shown in FIG. 3, a first silicon substrate 14 that is composed of silicon single crystal and has an outer diameter of 300 mm and a thickness of 0.78 mm was first subjected to a heat treatment by being maintained in a wet oxygen atmosphere at 1000° C. for 20 minutes, so as to form a first oxide film 21 with a thickness of 150 nm on the surfaces of the first silicon substrate 14. Hydrogen ions were then implanted into the top surface of the first silicon substrate 14 at a dose of 6×10¹⁶/cm² and at an energy level of 50 keV to form an ion implant region 16 inside the first silicon substrate 14 (FIG. 3(b)). A 100 nm portion of the first oxide film 21 was subsequently removed by HF etching so that the first oxide film 21 with a thickness of 50 nm remained on the first silicon substrate 14 (FIG. 3(d)).

A second silicon substrate 12 with the same shape and size as those of the first silicon substrate 14 was prepared separately (FIG. 3(c)). The second silicon substrate 12 was subjected to a heat treatment by being maintained in a wet oxygen atmosphere at 1000° C. for 15 minutes, so as to form a second oxide film 22 with a thickness of 100 nm on the surfaces of the second silicon substrate 12 (FIG. 3(e)). The second silicon substrate 12 was tightly attached to the hydrogen ion-implanted surface of the first silicon substrate 14 with the first oxide film 21 and the second oxide film 22 interposed therebetween, thereby forming a laminate 15 (FIG. 3(f)).

The laminate 15 was then subjected to a heat treatment in a nitrogen atmosphere at 500° C. for 30 minutes to be split along the ion implant region 16 (FIG. 3(g)), thus resulting in a laminated substrate 18 in which an upper SOI layer 13 was tightly attached to the second silicon substrate 12 with the first oxide film 21 and the second oxide film 22 therebetween (FIG. 3(h)). Any layer that has been damaged during removal was removed from the laminated substrate 18 through oxidation, and then the laminated substrate 18 was subjected to a high-temperature heat treatment in an argon atmosphere to completely strengthen the adhesion of the laminated interface. The top surface of the laminated structure 18 was then planarized (FIGS. 3(h) and (j)). The laminated structure 18 was subsequently thinned until a predetermined thickness was achieved for the SOI layer through a heat treatment in an oxidizing atmosphere. The SOI substrate 11 according to first example was thus obtained (FIG. 3(l)).

### First Comparative Example

Although not illustrated in the drawings, a first silicon substrate that is composed of silicon single crystal and has the same shape and size as those of the first silicon substrate used in first example was prepared. The first silicon substrate was subjected to a heat treatment by being maintained in an oxygen atmosphere at 1000° C. for 20 minutes, so as to form a first oxide film with a thickness of 150 mm on the surfaces of the first silicon substrate. Then, hydrogen ions were implanted into the top surface of the first silicon substrate at a dose of 6×10¹⁶/cm² and at an energy level of 50 keV to form an ion implant region inside the first silicon substrate.

A second silicon substrate with the same shape and size as those of the first silicon substrate was prepared separately, and then the second silicon substrate was tightly attached to the first silicon substrate with the first oxide film interposed therebetween, thereby forming a laminate.

The laminate was then subjected to a heat treatment in a nitrogen atmosphere at 500° C. for 30 minutes to be split along the ion implant region, thus resulting in a laminated substrate in which an upper SOI layer was tightly attached to the second silicon substrate with the second oxide film therebetween. Any layer that has been damaged during removal was removed from the laminated substrate through oxidation, and then the laminated substrate was further subjected to a high-temperature heat treatment in an argon atmosphere to completely strengthen the adhesion of the laminated interface. The top surface of the laminated structure was then planarized. The laminated structure was subsequently thinned until a predetermined thickness was achieved for the SOI layer through a heat treatment in an oxidizing atmosphere, thereby giving an SOI substrate. The SOI substrate according to first comparative example was thus obtained without removing the oxide film formed on the first silicon substrate.

### First Comparison Test

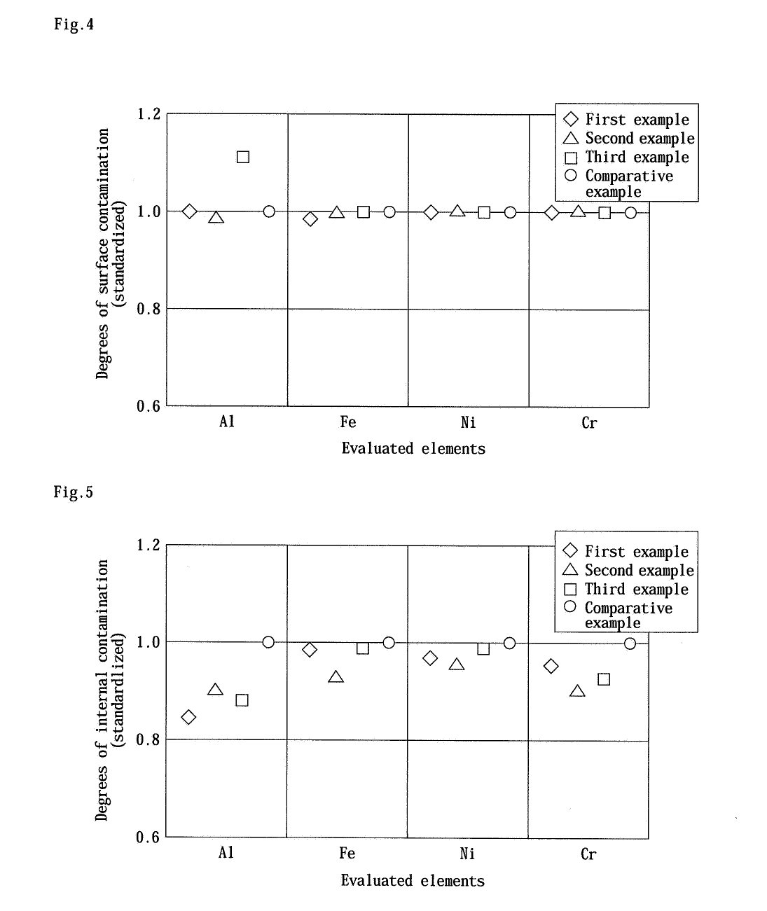

In each of first to third examples, the degrees of contamination from Al, Fe, Ni, and Cr on the top surface of the first oxide film after the implantation of hydrogen ions were measured. Also in first comparative example, the degrees of contamination from Al, Fe, Ni, and Cr on the top surface of the first silicon substrate after the implantation of hydrogen ions were measured. The measurements were performed by inductively coupled plasma spectrometry. FIG. 4 shows the degrees of contamination for each of first to third examples, assuming that the degrees of contamination for first comparative example were 1.0.

### Second Comparison Test

In each of first to third examples, the degrees of contamination from Al, Fe, Ni, and Cr inside the first silicon substrate after the implantation of hydrogen ions and the subsequent removal of a portion of or the entire first oxide film were measured. Also in first comparative example, the degrees of contamination from Al, Fe, Ni, and Cr inside the first silicon substrate after the implantation of hydrogen ions were measured. The degrees of contamination were measured at a depth of 1 μm from the top surface of the first silicon substrate, using atomic absorption spectrometry. FIG. 5 shows the degrees of contamination for each of first to third examples, assuming that the degrees of contamination for first comparative example were 1.0.

### Third Comparison Test

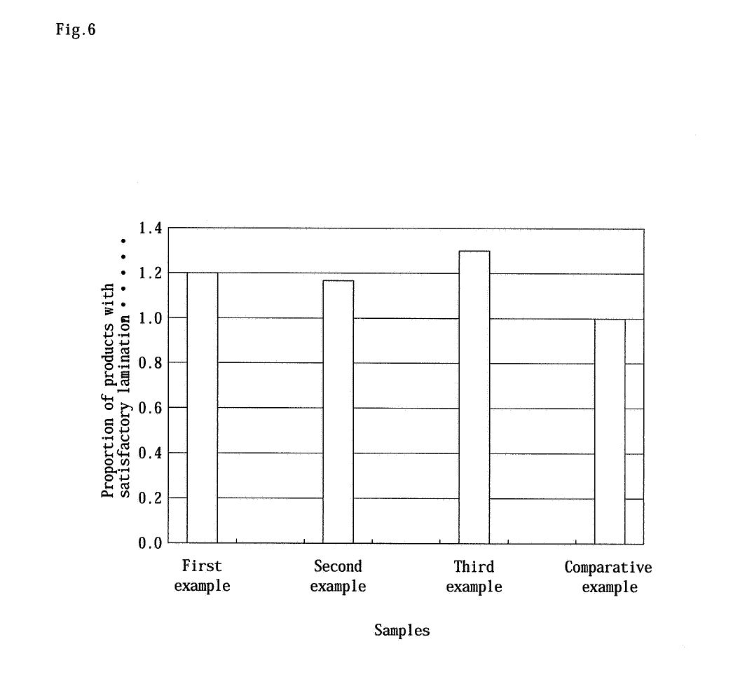

One-hundred SOI substrates according to each of first to third examples were fabricated, and the number of acceptable products among these substrates was measured. One-hundred SOI substrates according to first comparative example were also fabricated, and the number of acceptable products among these substrates was measured. Through visual inspections, SOI substrates free of voids and blisters on their top surface were determined to be non-defective, and SOI substrates with voids or blisters on their top surface were determined to be defective. FIG. 6 shows the proportion of acceptable products for each of first to third examples, assuming that the proportion of acceptable products for first comparative example is 1.0.

### Evaluation

As can be clearly seen from the results of FIG. 4, with respect to the degrees of contamination on the top surface of the first oxide film, i.e., the top surface of the first silicon substrate for use in manufacturing SOI substrates, there was no substantial difference between examples and comparative example, and their degrees of contamination were almost equal.

However, the results presented in FIG. 5 clearly show that possible internal contamination was reduced in the SOI substrates according to first to third examples from which a portion of or the entire first oxide film formed on the surfaces of the first silicon substrate was removed, compared with those according to first comparative example. This demonstrates that internal contamination can be reduced in SOI substrates manufactured according to the method of the invention that comprises removing the entire or a portion of the first oxide film formed on the surfaces of the first silicon substrate.

Moreover, as can be clearly seen from FIG. 6, the proportion of acceptable products was improved for each of first to third examples over first comparative example. This can be attributed to the fact that the decreases in internal contamination of the SOI substrates according to first to third examples were larger than that of the SOI substrates according to first comparative example.

What is claimed is:

1. A method for manufacturing an SOI substrate, comprising steps of:
forming a first oxide film (21) on a surface of a first silicon substrate (14);
implanting hydrogen ions into the surface of the first silicon substrate (14) on which the first oxide film (21) is formed to form an ion implant region (16) inside the first silicon substrate (14);
removing the entire first oxide film (21);
forming a second oxide film (22) on a surface of a second silicon substrate (12);
forming a laminate (15) by bonding the second silicon substrate (12) to a hydrogen ion-implanted surface of the first silicon substrate (14) with the second oxide film (22) interposed therebetween; and
subjecting the laminate (15) to a heat treatment at a predetermined temperature to separate the first silicon substrate (14) along the ion implant region (16), thereby obtaining an SOI substrate (11) including a thin SOI layer (13) formed on the second silicon substrate (12) with the second oxide film (22) interposed therebetween.

2. The method of claim it wherein the thickness of the first oxide film (21) formed on the surface of the first silicon substrate (14) is from 30 to 500 nm.

3. A method for manufacturing an SOI substrate, comprising steps of:
forming a first oxide film (21) on a surface of a first silicon substrate (14);
implanting hydrogen ions into the surface of the first silicon substrate (14) on which the first oxide film (21) is formed to form an ion implant region (16) inside the first silicon substrate (14);
removing a portion of the first oxide film (21);
forming a laminate (15) by bonding a second silicon substrate (12) to a hydrogen ion-implanted surface of the first silicon substrate (14) with the first oxide film (21) interposed therebetween; and
subjecting the laminate (15) to a heat treatment at a predetermined temperature to separate the first silicon substrate (14) along the ion implant region (16), thereby obtaining an SOI substrate (11) including a thin SOI layer (13) formed on the second silicon substrate (12) with the first oxide film (21) interposed therebetween.

4. The method of claim 3, wherein the thickness of a removed portion of the first oxide film (21) formed on the surface of the first silicon substrate (14) is from 30 to 500 nm.

5. A method for manufacturing an SOI substrate, comprising steps of:
forming a first oxide film (21) on a surface of a first silicon substrate (14);
implanting hydrogen ions into the surface of the first silicon substrate (14) on which the first oxide film (21) is formed to form an ion implant region (16) inside the first silicon substrate (14);
removing a portion of the first oxide film (21);
forming a second oxide film (22) on a surface of a second silicon substrate (12);
forming a laminate (15) by bonding the second silicon substrate (12) to a hydrogen ion-implanted surface of the first silicon substrate (14) so that the second oxide film (22) is laminated to the first oxide film (21); and
subjecting the laminate (15) to a heat treatment at a predetermined temperature to separate the first silicon substrate (14) along the ion implant region (16), thereby obtaining an SOI substrate (11) including a thin SOI layer (13) formed on the second silicon substrate (12) with the first oxide film (21) and the second oxide film (22) interposed therebetween.

6. The method of claim 5, wherein the thickness of a removed portion of the first oxide film (21) formed on the surface of the first silicon substrate (14) is from 30 to 500 nm.

7. The method of claim 1 wherein the hydrogen ions are implanted at a dose o 4×10¹⁶ to 10×10¹⁶ atoms/cm² and at an energy level of 20 to 200 keV.

8. The method of claim 1 wherein the second oxide film has a thickness of 10 to 300 nm.

9. The method of claim 1 wherein the laminate is subjected to a first heat treatment in a nitrogen atmosphere at a temperature from 400 to 800° C. for 1 to 30 minutes.

10. The method of claim 3 wherein the hydrogen ions are implanted at a dose o 4×10¹⁶ to 10×10¹⁶ atoms/cm² and at an energy level of 20 to 200 keV.

11. The method of claim 3 wherein the laminate is subjected to a first heat treatment in a nitrogen atmosphere at a temperature from 400 to 800° C. for 1 to 30 minutes.

12. The method of claim 5 wherein the hydrogen ions are implanted at a dose o 4×10¹⁶ to 10×10¹⁶ atoms/cm² and at an energy level of 20 to 200 keV.

13. The method of claim 5 wherein after the removal of a portion of the second oxide film, the sum of the thicknesses of the first and second oxide films is 10 to 300 nm.

14. The method of claim 5 wherein the laminate is subjected to a first heat treatment in a nitrogen atmosphere at a temperature from 400 to 800° C. for 1 to 30 minutes.

15. An SOI substrate made by the method of claim 1.

16. An SOI substrate made by the method of claim 3.

17. An SOI substrate made by the method of claim 5.
